(19) United States
(12) Patent Application Publication
(10) Pub. No.: US 2015/0303170 A1
(43) Pub. Date: Oct. 22, 2015

(54) SINGULATED UNIT SUBSTRATE FOR A SEMICONDCUTOR DEVICE

(71) Applicant: Amkor Technology, Inc., Chandler, AZ (US)

(72) Inventors: Keun Soo Kim, Gyeonggi-do (KR); Byoung Jun Ahn, Seoul (KR); Choon Heung Lee, Seoul (KR); Jin Young Kim, Seoul (KR); Dae Byoung Kang, Seoul (KR); Roger St. Amand, Tempe, AZ (US)

(73) Assignee: Amkor Technology, Inc., Chandler, AZ (US)

(21) Appl. No.: 14/255,726

(22) Filed: Apr. 17, 2014

(51) Int. Cl. H01L 23/00; H01L 21/56; H01L 21/78; H01L 23/522; H01L 23/31

(52) U.S. Cl. CPC H01L 24/97; H01L 23/5226; H01L 23/3114; H01L 24/17; H01L 21/78; H01L 21/561; H01L 2224/1705; H01L 2224/1712; H01L 2224/95001

(57) ABSTRACT

A singulated substrate for a semiconductor device may include a singulated unit substrate comprising circuit patterns on a top surface and a bottom surface of the singulated unit substrate. A semiconductor die may be bonded to the top surface of the singulated unit substrate. An encapsulation layer may encapsulate the semiconductor die and cover the top surface of the singulated unit substrate. The side surfaces of the singulated unit substrate between the top surface and bottom surface of the singulated unit substrate may be coplanar with side surfaces of the encapsulation layer. The semiconductor die may be electrically coupled to the singulated unit substrate utilizing solder bumps. Solder balls may be formed on the circuit patterns on the bottom surface of the singulated unit substrate. An underfill material may be formed between the semiconductor die and the top surface of the singulated unit substrate.

### CROSS REFERENCE TO RELATED APPLCIATIONS

N/A

### FIELD OF THE INVENTION

Certain embodiments of the invention relate to semiconductor chip packaging. More specifically, certain embodiments of the invention relate to a singulated substrate for a semiconductor device.

### BACKGROUND OF THE INVENTION

In general, a manufacturing method of a semiconductor device includes preparing a substrate, electrically connecting a semiconductor die to the substrate, encapsulating the substrate with an encapsulant, bonding a solder ball to the substrate, and sawing the substrate to separate the substrate into individual semiconductor device. In this scenario, a common substrate consists of good units and failed units in that the substrate includes a plurality of units to each of which a semiconductor die is electrically connected, and the plurality of units are divided into good units and failed units. The semiconductor die is not connected to the fail unit, but an encapsulant is provided in a gang molding method, for example. Accordingly, the failed unit of the substrate may lower the manufacturing yield of semiconductor devices and unnecessary consumption of materials may be caused.

Further limitations and disadvantages of conventional and traditional approaches will become apparent to one of skill in the art, through comparison of such systems with the present invention as set forth in the remainder of the present application with reference to the drawings.

### FIELD OF THE INVENTION

The present invention relates to a manufacturing method of a semiconductor device using a singulated unit substrate and a semiconductor device manufactured thereby.

### BRIEF SUMMARY OF THE INVENTION

A singulated substrate for a semiconductor device, substantially as shown in and/or described in connection with at least one of the figures, as set forth more completely in the claims.

Various advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIGS. 1A to 1G are cross-sectional views illustrating a manufacturing method of a semiconductor device using a singulated unit substrate, in accordance with an example embodiment of the present invention.

FIG. 2 is a plan view illustrating a state in which a singulated unit substrate is mounted on a carrier in the manufacturing method of the semiconductor device.

FIGS. 3A to 3E are cross-sectional views illustrating a manufacturing method of a semiconductor device using a singulated unit substrate according to an example embodiment of the present invention.

### DETAILED DESCRIPTION OF THE INVENTION

Certain aspects of the invention may be found in a singulated substrate for a semiconductor device. Example aspects of the invention may include a singulated substrate for a semiconductor device. The semiconductor device may comprise a singulated unit substrate comprising circuit patterns on a top surface and a bottom surface of the singulated unit substrate. A semiconductor die may be bonded to the top surface of the singulated unit substrate. An encapsulation layer may encapsulate the semiconductor die and cover the top surface of the singulated unit substrate. The side surfaces of the singulated unit substrate between the top surface and bottom surface of the singulated unit substrate may be coplanar with side surfaces of the encapsulation layer. The semiconductor die may be electrically coupled to the singulated unit substrate utilizing solder bumps. Solder balls may be formed on the circuit patterns on the bottom surface of the singulated unit substrate. An underfill material may be formed between the semiconductor die and the top surface of the singulated unit substrate. The singulated unit substrate may comprise conductive vias that electrically couple the circuit patterns on the top surface and bottom surface of the singulated unit substrate. The circuit patterns on the top surface and bottom surface of the singulated unit substrate may be separated by a dielectric layer.

In accordance with an example embodiment of the present invention, there is provided a manufacturing method of a semiconductor device, the manufacturing method including preparing a carrier having a first surface that may be planar and a second surface that may be planar and opposite to the first surface, positioning a plurality of singulated unit substrates spaced apart from each other on the first surface of the carrier, electrically connecting a semiconductor die to each of the plurality of singulated unit substrates, encapsulating first surface of the carrier, the plurality of singulated unit substrates, and the semiconductor die with an encapsulant, separating the carrier from the plurality of singulated unit substrates and the encapsulant, and singulating the encapsulant between the spaced-apart singulated unit substrates and isolating individual semiconductor devices.

After the separating of the carrier, the manufacturing method may further include electrically connecting solder balls to the plurality of singulated unit substrates. A distance between the spaced-apart singulated unit substrates may be in a range of 50 to 500 microns. The isolating of the individual semiconductor devices may include singulating the encapsulant using a blade having a width in a range of 50 to 500 microns. A temporary film may further be disposed between the carrier and the singulated unit substrates. In the separating of the carrier, the temporary film may be separated from the plurality of singulated unit substrates and the encapsulant.

Each of the singulated unit substrates may include a first surface that is planar and faces the semiconductor die, a second surface that may be planar and opposite to the first surface, and a third surface that connects the first surface and the second surface, and in the isolating of the individual semiconductor devices, the third surface of the singulated unit substrate may be coplanar with a vertical surface of the encapsulant. The electrically connecting of the semiconductor die may include electrically connecting the semiconductor die to the singulated unit substrate using a solder bump, and in the encapsulating, the encapsulant may be injected into a gap between the singulated unit substrate and the semiconductor die to surround the solder bump.

In accordance with an example embodiment of the present invention, there is also provided a semiconductor device including a singulated unit substrate; a semiconductor die electrically connected to the singulated unit substrate; and an encapsulant encapsulating the semiconductor die electrically connected to the singulated unit substrate, wherein the singulated unit substrate and a vertical surface of the encapsulant may be coplanar. The semiconductor device may further include a plurality of solder balls electrically connected to the singulated unit substrate.

In accordance with an example embodiment of the present invention, there is also provided a manufacturing method of a semiconductor device, the manufacturing method including preparing a carrier having a first surface that may be planar and a second surface that may be planar and opposite to the first surface; positioning a plurality of singulated unit substrates spaced apart from each other on the first surface of the carrier; electrically connecting a semiconductor die to each of the plurality of singulated unit substrates; sequentially stacking an encapsulant film and a preimpregnated material (pre-preg) on the first surface of the carrier, the plurality of singulated unit substrates, and the semiconductor die and encapsulating the same; separating the carrier from the plurality of singulated unit substrates and the encapsulant film; and singulating the encapsulant film and the pre-preg between the spaced-apart singulated unit substrates and isolating individual semiconductor devices.

After the separating of the carrier, the manufacturing method may further include electrically connecting solder balls to the plurality of singulated unit substrates. A distance between the spaced-apart singulated unit substrates may be in a range of 50 to 500 microns. The isolating of the individual semiconductor devices may include singulating the encapsulant film and the pre-preg using a blade having a width in a range of 50 to 500 microns. A temporary film may further be disposed between the carrier and the singulated unit substrates. In the separating of the carrier, the temporary film may be separated from the plurality of singulated unit substrates and the encapsulant film.

Each of the singulated unit substrates may include a first surface that may be planar and faces the semiconductor die, a second surface that may be planar and is opposite to the first surface, and a third surface that connects the first surface and the second surface. In the isolating of the individual semiconductor devices, the third surface of the singulated unit substrate may be coplanar with vertical surfaces of the encapsulant film and the pre-preg. The electrically connecting of the semiconductor die may include electrically connecting the semiconductor die to the singulated unit substrate using a solder bump, and an encapsulant film may be inserted into a gap between the singulated unit substrate and the semiconductor die to surround the solder bump.

In accordance with an example embodiment of the present invention, there is also provided a semiconductor device including a singulated unit substrate; a semiconductor die electrically connected to the singulated unit substrate; an encapsulant film inserted between a gap between the singulated unit substrate and the semiconductor die; and a preimpregnated material (pre-preg) encapsulating the semiconductor die positioned on the encapsulant film, wherein vertical surfaces of the singulated unit substrate, the encapsulant film and the pre-preg are coplanar.

The semiconductor device may further include a plurality of solder balls electrically connected to the singulated unit substrate. As described above, in the manufacturing method of the semiconductor device using a good singulated unit substrate and the semiconductor device manufactured thereby, since the semiconductor device is manufactured using only the good singulated unit substrate, the manufacturing yield of the semiconductor device can be improved.

In the drawing figures, the dimensions of layers and regions may be exaggerated for clarity of illustration. Like reference numerals refer to like elements throughout. As used herein, the term “and/or” includes any and all combinations of one or more of the associated listed items.

The terminology used herein is for the purpose of describing particular embodiments only and is not intended to be limiting of the invention. As used herein, the singular forms are intended to include the plural forms as well, unless the context clearly indicates otherwise. It will be further understood that the terms “comprise” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that, although the terms first, second, etc. may be used herein to describe various elements, components, regions, layers and/or sections, these elements should not be limited by these terms. These terms are only used to distinguish one element from another element, component, region, layer and/or section. Thus, for example, a first element, a first component, a first region, a first layer and/or a first section discussed below could be termed a second element, a second component, a second region, a second layer and/or a second section without departing from the teachings of the present invention.

In addition, as used herein, the term “singulated unit substrates” is intended to mean only a good unit substrate tested and singulated through a testing step and a sawing step performed on a panel substrate having a plurality of units including good and failed products. That is to say, a failed unit is not included in the singulated unit substrate.

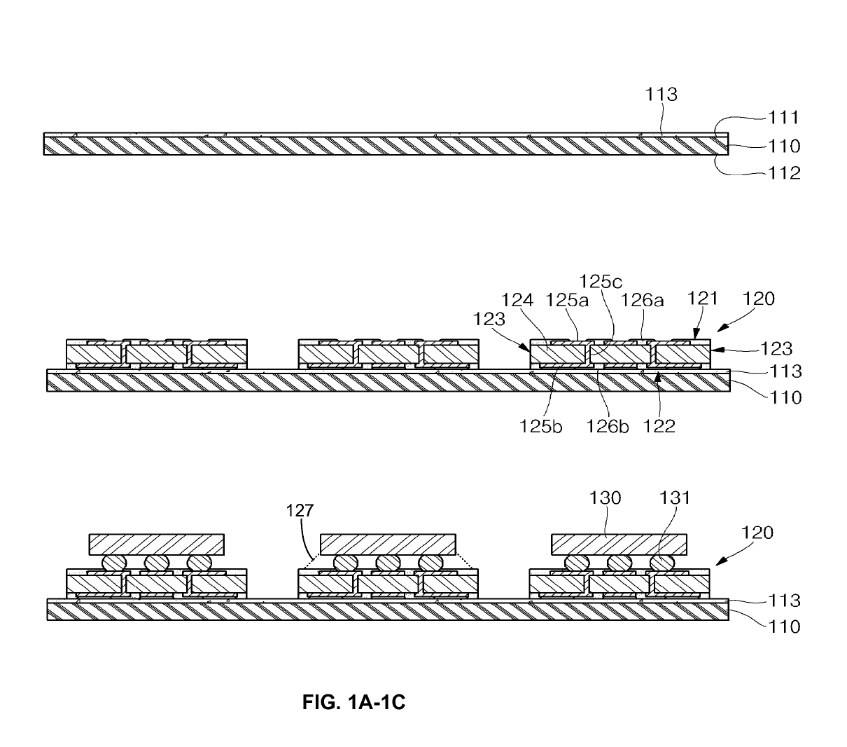

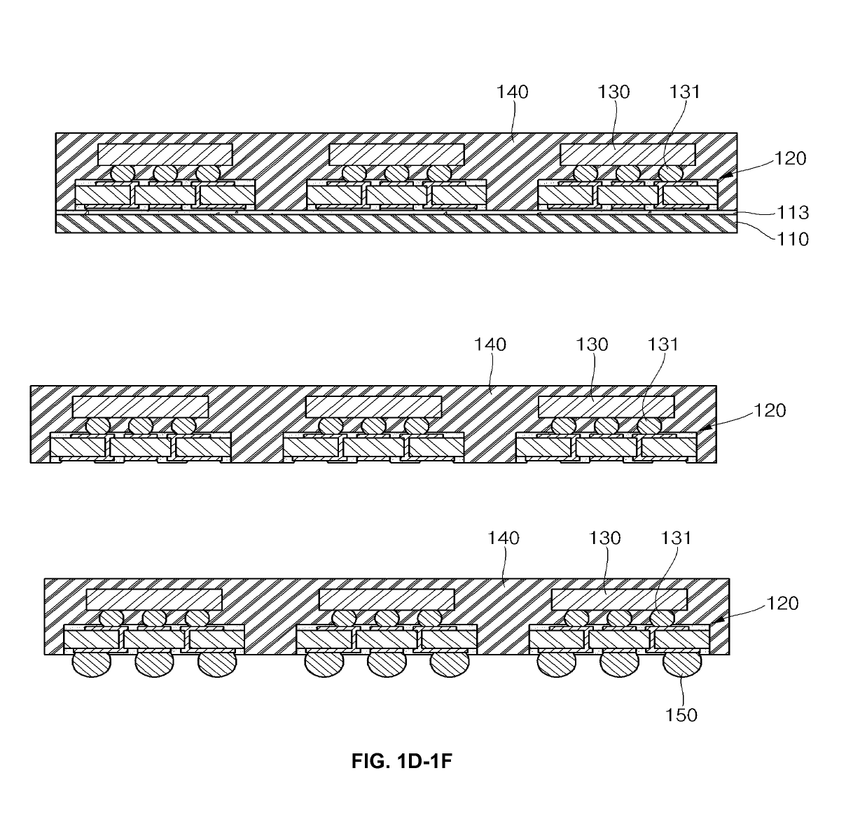

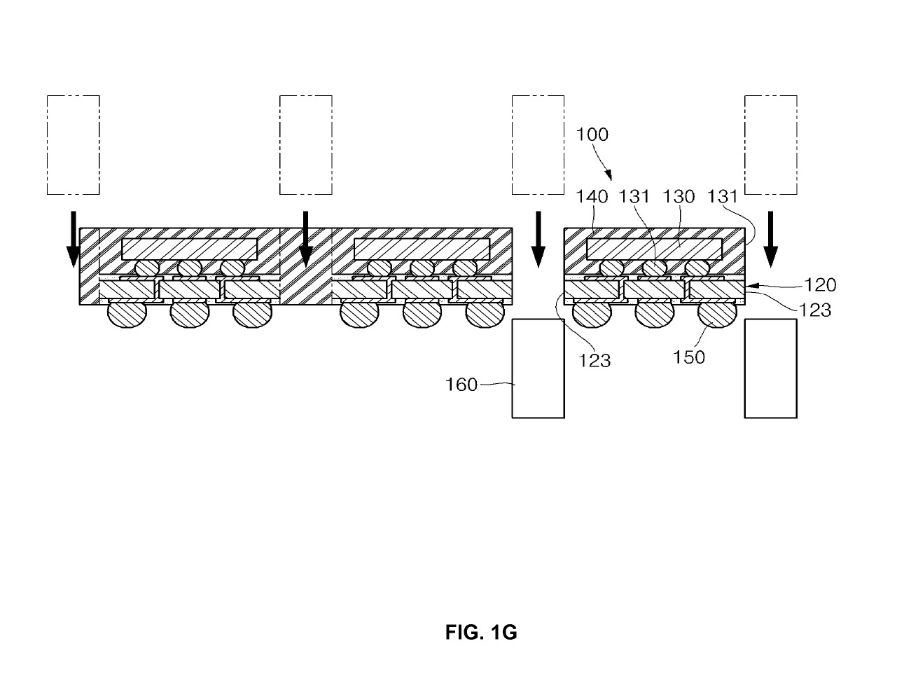

Referring to FIGS. 1A to 1G, cross-sectional views illustrating a manufacturing method of a semiconductor device using a singulated unit substrate according to example embodiments of the present invention and a semiconductor device manufactured thereby are illustrated.

The manufacturing method of a semiconductor device using a singulated unit substrate according to example embodiments of the present invention includes preparing a carrier, positioning a plurality of singulated unit substrates, electrically connecting a semiconductor die to each of the plurality of singulated unit substrates, encapsulating, separating the carrier, electrically connecting solder balls to the plurality of singulated unit substrates, and singulating.

As illustrated in FIG. 1A, in the carrier preparing, a carrier 110 having a first surface 111 that is roughly planar and a second surface 112 that is roughly planar and opposite to the first surface 111, is prepared. The carrier 110 may include at least one selected from the group consisting of a metal, flame retardant composition-4 (FR-4), bisaleimide triazine (BT), and equivalents thereof, but the present invention does not necessarily limit the material of the carrier 110 to those listed herein.

In addition, in order to make the carrier 110 easily separated from the singulated unit substrates 120 and the encapsulant 140 in a subsequent process, a temporary film 113 may be adhered to the first surface 111 of the carrier 110. The temporary film 113 may be a film having adhesion that may be removed or reduced by irradiating UV rays thereon or applying heat thereto. The temporary film 113 may also be easily peeled off at room temperature (˜25 degrees C.).

The temporary film 113 may be made of a material that is the same as or different from that of the carrier 110. In addition, the temporary film 113 may be separated from the carrier 110 or may be integrally formed with the carrier 110.

As illustrated in FIG. 1B, in the positioning of the plurality of singulated unit substrates, the plurality of singulated unit substrates 120 spaced apart from each other are positioned on the first surface 111 of the carrier 110 or the temporary film 113.

Here, each of the singulated unit substrates 120 may comprise a first surface 121 that may be roughly planar and faces a semiconductor die 130 to be described later, a second surface 122 that is roughly planar and opposite to the first surface 121 and faces the carrier 110, and a third surface 123 connecting the first and second surfaces 121 and 122.

In addition, a first circuit pattern 125a may be formed on the first surface 121 and a second circuit pattern 125b may be formed on the second surface 122, about an insulating layer 124 in each of the singulated unit substrates 120, and the first and second circuit patterns 125a and 125b may be connected to each other by a conductive via 125c. Insulating material 126a and 126b may be formed on the top and bottom surfaces of the singulated unit substrates 120 to provide electrical isolation between the conductive traces in the circuit patterns 125a and 125b and also to protect the top and bottom surfaces of the singulated unit substrates 120.

The singulated unit substrates 120 may comprise devices that pass desired operability and/or performance tests with the first and second circuit patterns 125a and 125b. The singulated unit substrates 120 may be one selected from a general rigid printed circuit board, a flexible printed circuit board, a ceramic board, and equivalents thereof, but the present invention does not necessarily limit the material of the singulated unit substrate 120 to those listed herein.

A distance between the spaced-apart singulated unit substrates 120, that is, a distance between third surfaces 123 of the singulated unit substrates 120 different from each other, may be in a range of approximately 50 to 500 microns. Here, if the distance is greater than approximately 500 microns, a relatively large amount of the encapsulant 140 may need to be removed when singulating the substrates, increasing the singulation time.

As illustrated in FIG. 1C, the semiconductor die 130 may be electrically connected to the first circuit pattern 125a of each of the singulated unit substrates 120 using a solder bump 131. Here, a predetermined gap may be formed between the semiconductor die 130 and each of the singulated unit substrates 120. The semiconductor die 130 may be connected to the first circuit pattern 125a of each of the singulated unit substrates 120 using a copper filler (not shown) and a solder cap (not shown), instead of the solder bump 131.

As illustrated in FIG. 1D, the first surface 111 of the carrier 110, the singulated unit substrates 120 and the semiconductor die 130 may be encapsulated by the encapsulant 140. In such a manner, the encapsulant 140 may completely surround the first surface 111 of the carrier 110 between the singulated unit substrates 120, the first surface 121 and the third surface 123 of each of the singulated unit substrates 120, except for the regions of the substrates connected to the solder bump 131, and the semiconductor die 130, except for the region on the die connected to the solder bump 131.

During encapsulation, the encapsulant 140 may be injected into gaps between the singulated unit substrates 120 and the semiconductor die 130 and may surround the solder bump 131.

The encapsulating may be achieved by a general molding method selected from a transfer molding method, an injection molding method, a compression molding method, a profile extrusion, and equivalents thereof, but the present invention does not necessarily limit the encapsulating method to those listed herein.

Before encapsulation, an optional underfill 127 may be injected into gaps between the singulated unit substrates 120 and the semiconductor die 130, as illustrated in FIG. 1C.

As illustrated in FIG. 1E, the carrier 110 may be separated from the plurality of singulated unit substrates 120 and the encapsulant 140. Here, if the temporary film 113 is interposed between each of the plurality of singulated unit substrates 120, the encapsulant 140 and the carrier 110, then the carrier 110 may be more easily separated. In particular, if adhesion between the carrier 110 and the temporary film 113 is smaller than adhesion between the temporary film 113 and the encapsulant 140, the separating of the carrier 110 may be more easily achieved. In other words, it may be easier to separate the carrier 110 from the temporary film 113 than to separate the carrier 110 directly from the encapsulant 140.

In addition, as described above, if the temporary film 113 loses its adhesion by UV irradiation, UV rays may be irradiated into the temporary film 113, thereby more easily separating the temporary film 113 from the plurality of singulated unit substrates 120 and the encapsulant 140.

The second surface 122 and a bottom surface of the encapsulant 140 of the singulated unit substrate 120 may be exposed in the removal of the temporary film 113. In particular, the second circuit pattern 125b provided in the singulated unit substrate 120 may be exposed to the outside.

As illustrated in FIG. 1F, solder balls 150 may be electrically connected to the plurality of singulated unit substrates 120. The solder balls 150 may be electrically connected to the second circuit pattern 125b provided in each of the plurality of singulated unit substrates 120.

As an example, a volatile flux may be formed on the second circuit pattern 125b, the solder balls 150 may be temporarily adhered to the volatile flux, followed by heating to a range of approximately 150 to 250 degrees C. to the resultant structure, thereby making the flux volatilized for removal and melting the solder balls 150 to the second circuit pattern 125b for electrical connectivity.

Thereafter, if the solder balls 150 are cooled to room temperature (˜25 degrees C.), the solder balls 150 may have substantially spherical shapes due to surface tension and may be electrically connected to the singulated unit substrates 120 more firmly.

As illustrated in FIG. 1G, the encapsulant 140 between the spaced-apart singulated unit substrates 120 may be singulated for removal, thereby providing individual semiconductor devices 100.

Here, the isolating of the individual semiconductor devices 100 may be achieved by singulating the encapsulant 140 using a blade 160 (e.g., a saw blade) having a width in a range of approximately 50 to 500 microns. Also for example, singulating may be performed using a laser or other directed energy cutting device, water jet or other directed-matter cutting mechanism, etc.

In addition, in the isolating of the individual semiconductor devices 100, the third surface 123 of each of the singulated unit substrates 120 may be coplanar with vertical surfaces of the encapsulant 140. Since the distance between the singulated unit substrates 120 and the width of the saw blade 160 (or the cut, for example a single cut or multiple cuts on the same saw street) may be substantially equal to each other, or the width of the saw blade 160 (or the cut, for example a single cut or multiple cuts on the same saw street) may be greater than the distance between the singulated unit substrates 120, the third surface 123 of each of the singulated unit substrates 120 might not be surrounded by the encapsulant 140 but exposed to the outside. Therefore, the semiconductor device 100 may be further reduced in size. Note that in various examples, the width of the saw blade 160 (or the cut) might be narrower than the distance between the singulated unit substrates 120.

In an example implementation the substrates 120 may be oversized in anticipation of the edges of the substrates 120 being cut during the singulation process. For example, the saw blade 160 (or the cut) may then be selected to be wide enough to cut both the mold material in the space between the substrates and the edges of the substrates.

In such a manner, in an example embodiment of the present invention, the semiconductor devices 100 may be manufactured using only good singulated unit substrates 120, thereby increasing the manufacturing yield of the semiconductor device 100 to approximately 100%.

Meanwhile, as illustrated in FIG. 1G, the unitary or independent semiconductor device 100 according to an example embodiment of the present invention includes the singulated unit substrate 120, the semiconductor die 130 electrically connected to the singulated unit substrate 120 through the solder bump 131, the encapsulant 140 encapsulating the semiconductor die 130, and the plurality of solder balls 150 electrically connected to the singulated unit substrate 120.

In addition, in the semiconductor device 100 according to an example embodiment of the present invention, the third surface 123 of the singulated unit substrate 120 and the vertical surfaces 131 of the encapsulant 140 may be coplanar, such that the third surface 123 of the singulated unit substrate 120 may be exposed to the outside through the vertical surfaces 131 of the encapsulant 140.

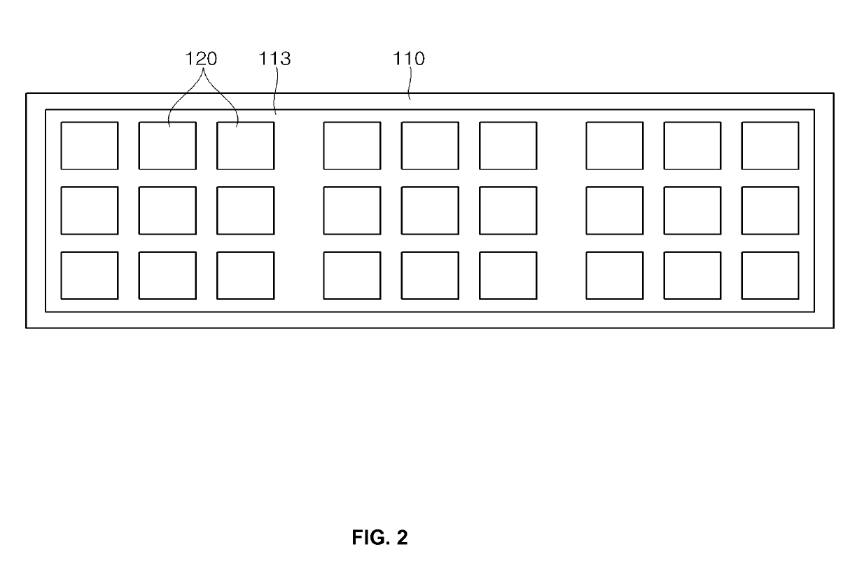

Referring to FIG. 2, a plan view illustrating a state in which a singulated unit substrate is mounted on a carrier in the manufacturing method of the semiconductor device, shown in FIG. 1, is illustrated.

As illustrated in FIG. 2, one temporary film 113 may be adhered onto one carrier 110, and 3×3 good singulated unit substrates 120 may be positioned or arrayed on the temporary film 113.

Here, an adhesive or glue may be coated on the temporary film 113 to allow the good singulated unit substrates 120 to be adhered to the temporary film 113. As described above, the adhesive or the glue may lose its adhesion by UV irradiation or heat. In another example scenario, the adhesive or the glue may have adhesion or viscosity so as to be separated at room temperature with a small force.

In addition, the 3×3 good singulated unit substrates 120 each including the semiconductor die 130 may be encapsulated with a lump of the encapsulant 140.

In the illustrated example embodiment, the 3×3 good singulated unit substrates 120 are exemplified, but aspects of the present invention are not necessarily limited thereto. Various numbers of singulated unit substrates 120 may be positioned or arrayed on the temporary film 113.

In addition, in the illustrated example embodiment, one temporary film 113 having the same area as that of the carrier 110 may be adhered to the carrier 110 but aspects of the present invention are not limited thereto. In some cases, multiple temporary films 113 may be provided.

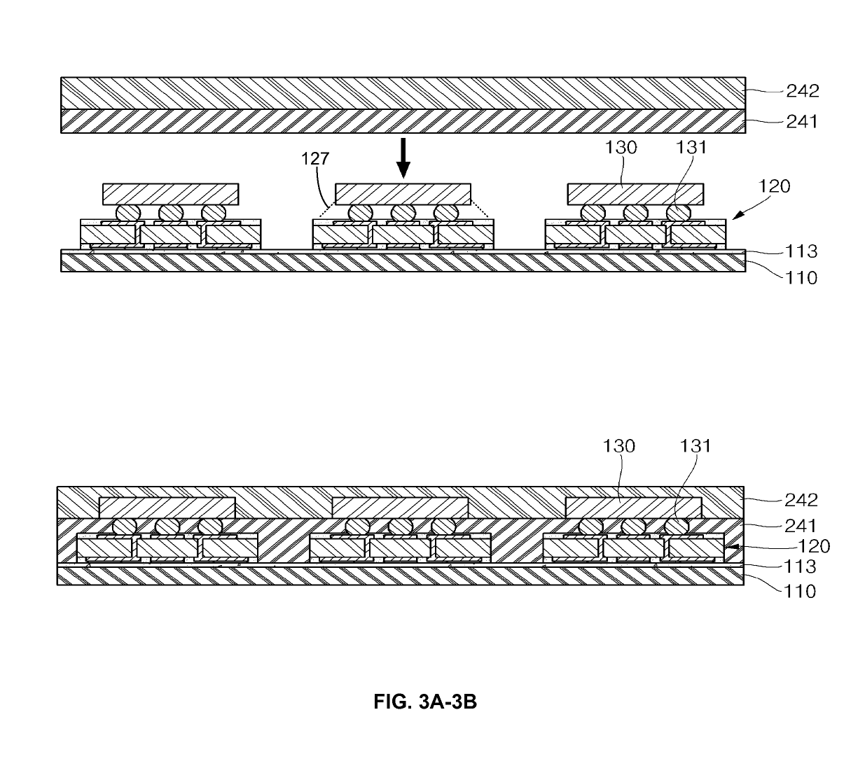

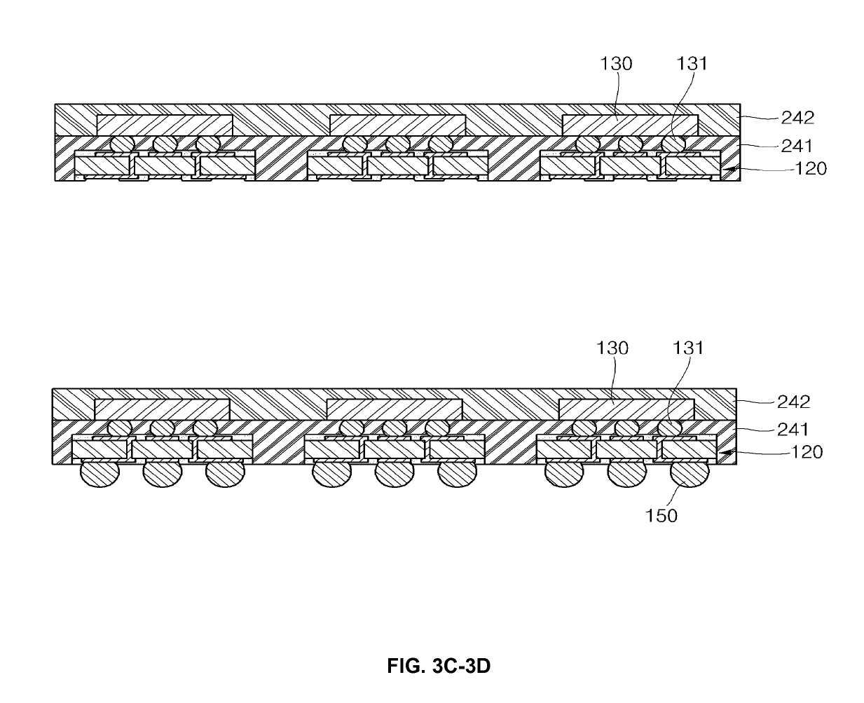

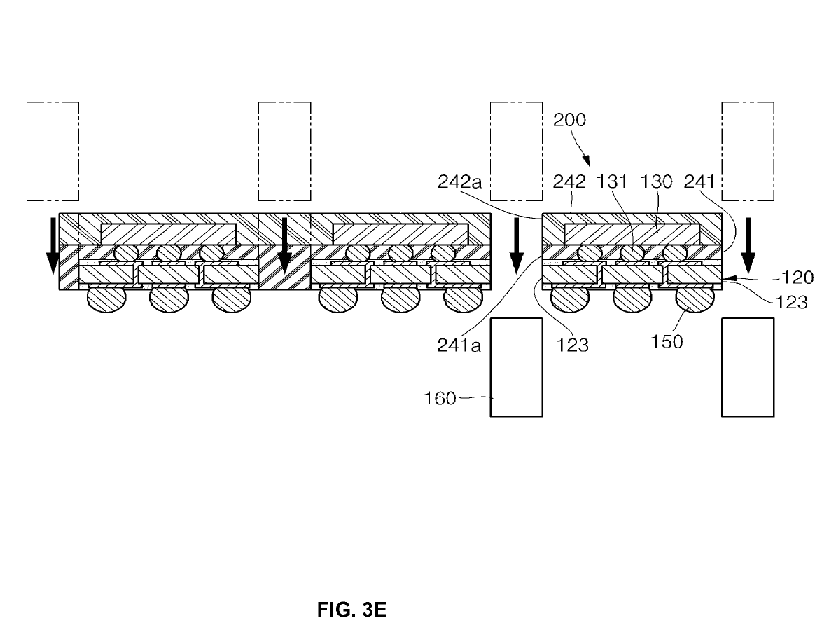

FIGS. 3A to 3E are cross-sectional views illustrating a manufacturing method of a semiconductor device using a singulated unit substrate and a semiconductor device manufactured thereby, according to example embodiments of the present invention.

The manufacturing method of the semiconductor device using the singulated unit substrate according to an example embodiment of the present invention includes preparing a carrier, positioning a plurality of singulated unit substrates, electrically connecting a semiconductor die to each of the plurality of singulated unit substrates, encapsulating using an encapsulant film and a preimpregnated material (pre-preg), separating the carrier, electrically connecting solder balls to the plurality of singulated unit substrates, and singulating.

As illustrated in FIG. 3A, a substantially plate-shaped encapsulant film 241 and a pre-preg 242 may be prepared. Here, the encapsulant film 241 may comprise a thermally curable resin with a filler (an in organic material, such as silica) and may be in an A- or B-stage (semicurable) state. In addition, the pre-preg 242 may comprise a thermally curable resin without a filler and may be in an A- or B-stage (semicurable) state. In another example scenario, an optional underfill material 127 may be injected between the semiconductor die 130 and the singulated unit substrates 120.

Here, the A-stage may comprise a stage in which a resin and a curing agent are simply mixed according to mixing ratio and a curing reaction does not take place at all, and the B-stage may comprise a stage in which a reaction between a resin and a curing agent takes place to some extent to rapidly increase the viscosity, and a material is not soluble in a solvent but is fusible by heat, forming flowability.

The encapsulant film 241 and the pre-preg 242 may be cured in B-stage in curing the resin and stored at a low temperature to delay a further reaction., Since a curing reaction takes place slowly at a low temperature of approximately−18 degrees C., but is still continuous, the encapsulant film 241 or the pre-preg 242 should be used within a shelf life. The shelf life may be affected by the type of curing agent used and the temperature, and may generally be in a range of approximately several hours to six months.

As described above, if the encapsulant film 241 and the pre-preg 242 are placed at a temperature within a predetermined range (approximately 25-200 degrees), the viscosity may be further lowered, and flowability may be improved. However, if the encapsulant film 241 and the pre-preg 242 are placed at a temperature in excess of the predetermined range, they may eventually be completely cured (C-stage).

Here, the C-stage may comprise a stage in which a reaction between a resin and a curing agent is almost finished or is completed and a material may be completely cured without being affected by a solvent or heat.

In addition, the pre-preg 242 may comprise a sheet-like product prepared by previously impregnating a binding agent in a reinforced fiber, that is, an intermediate material of a product of composite materials. The pre-preg 242 may be one of a glass fiber pre-preg, a carbon fiber pre-preg, a hybrid pre-preg, and equivalents thereof, but aspects of the present invention are not limited thereto. The pre-preg 242 may also be an Ajinomoto build-up film (ABF).

As illustrated in FIG. 3B, in the encapsulating, the encapsulant film 241 and the pre-preg 242 are stacked on the carrier 110, the singulated unit substrate 120 and the semiconductor die 130, and compressed at a predetermined temperature (approximately 25° C. to 200° C.). Then, the encapsulant film 241 may be placed in close contact with the first surface 111 of the carrier 110 exposed between the singulated unit substrates 120 and injected into a gap between the singulated unit substrate 120 and the semiconductor die 130 to then surround the solder bump 131. Here, the encapsulant film 241 may also make close contact with the first surface 121 and the third surface 123 of the singulated unit substrates 120, except for the region connected to the solder bump 131. In addition, the pre-preg 242 may completely surround vertical and top surfaces of the semiconductor die 130, thereby protecting the semiconductor die 130 from the external environment.

Thereafter, if the temperature is further increased, the encapsulant film 241 and the pre-preg 242 may be completely cured and hardened in the C-stage.

As illustrated in FIG. 3C, the carrier 110 may be separated from the singulated unit substrate 120 and the cured encapsulant film 241 for removal. Here, if the temporary film 113 is provided on the carrier 110, the temporary film 113 may also be separated from the carrier 110 for removal.

As illustrated in FIG. 3D, solder balls 150 may be electrically connected to the singulated unit substrates 120 to provide electrical contact to external devices and/or circuit boards, for example.

As illustrated in FIG. 3E, the encapsulant film 241 between the spaced-apart singulated unit substrates 120 and the pre-preg 242 may be singulated with a blade 160, thereby providing individual semiconductor devices 100.

Here, since the width of the blade 160 may be equal to a distance between the singulated unit substrates 120, the encapsulant film 241 or the pre-preg 242 does not exist on vertical surfaces (i.e., third surfaces 123) of the singulated unit substrates 120. That is to say, the vertical surfaces (i.e., the third surfaces 123) of the singulated unit substrate 120 may be coplanar with the encapsulant film 241 and/or the vertical surfaces 241a and 242a of the pre-preg 242.

In such a manner, in an example embodiment of the present invention, the semiconductor devices 200 are manufactured using only good singulated unit substrates 120, thereby increasing the manufacturing yield of the semiconductor device 200 of approximately 100%.

Meanwhile, as illustrated in FIG. 3E, the unitary or independent semiconductor device 200 includes the singulated unit substrate 120, the semiconductor die 130 electrically connected to the singulated unit substrate 120 through the solder bump 131, the encapsulant film 241 injected into the gap between each of the singulated unit substrates 120 and the semiconductor die 130, the pre-preg 242 encapsulating the semiconductor die 130 on the encapsulant film 241, and the plurality of solder balls 150 electrically connected to the singulated unit substrates 120.

In addition, as discussed previously in the discussion of FIG. 1G, in the semiconductor device 200, vertical surfaces 123, 241a and 242a of the singulated unit substrate 120, the encapsulant film 241 and the pre-preg 242 may be coplanar, for example using a saw blade 160 (or cut) that is wider than the gap between the singulated unit substrates 120. That is to say, the third surface 123 of the singulated unit substrate 120 is exposed to the outside through the vertical surface 241a of the encapsulant film 241. Additionally, as discussed previously with regard to FIG. 1G, the substrates may be oversized in anticipation of the edges of the substrates 120 being cut during the singulation process. The term “pre-preg 242” is also used in the completed semiconductor device 220, which may be, however, understood to be completely cured in the C stage, rather than in the A- or B-stage.

This disclosure provides exemplary embodiments of the present invention. The scope of the present invention is not limited by these exemplary embodiments. Numerous variations, whether explicitly provided for by the specification or implied by the specification, such as variations in structure, dimension, type of material and manufacturing process, may be implemented by one skilled in the art in view of this disclosure.

In an example embodiment of the invention, a singulated substrate for a semiconductor device may comprise a singulated unit substrate comprising circuit patterns on a top surface and a bottom surface of the singulated unit substrate. A semiconductor die may be bonded to the top surface of the singulated unit substrate. An encapsulation layer may encapsulate the semiconductor die and cover the top surface of the singulated unit substrate. The side surfaces of the singulated unit substrate between the top surface and bottom surface of the singulated unit substrate may be coplanar with side surfaces of the encapsulation layer. The semiconductor die may be electrically coupled to the singulated unit substrate utilizing solder bumps. Solder balls may be formed on the circuit patterns on the bottom surface of the singulated unit substrate. An underfill material may be formed between the semiconductor die and the top surface of the singulated unit substrate. The singulated unit substrate may comprise conductive vias that electrically couple the circuit patterns on the top surface and bottom surface of the singulated unit substrate. The circuit patterns on the top surface and bottom surface of the singulated unit substrate may be separated by a dielectric layer.

While the invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiments disclosed, but that the present invention will include all embodiments falling within the scope of the appended claims.

1. A semiconductor device comprising:
a singulated unit substrate comprising circuit patterns on a top surface and a bottom surface of the singulated unit substrate;
a semiconductor die bonded to the top surface of the singulated unit substrate;
an encapsulation layer encapsulating the semiconductor die and covering the top surface of the singulated unit substrate, wherein side surfaces of the singulated unit substrate between the top surface and bottom surface of the singulated unit substrate are cut to be coplanar with side surfaces of the encapsulation layer.

2. The semiconductor device according to claim 1, wherein the semiconductor die is electrically coupled to the singulated unit substrate utilizing solder bumps.

3. The semiconductor device according to claim 1, wherein solder balls are formed on the circuit patterns on the bottom surface of the singulated unit substrate.

4. The semiconductor device according to claim 1, wherein an underfill material is formed between the semiconductor die and the top surface of the singulated unit substrate.

5. The semiconductor device according to claim 1, wherein the singulated unit substrate comprises conductive vias that electrically couple the circuit patterns on the top surface and bottom surface of the singulated unit substrate.

6. The semiconductor device according to claim 1, wherein the circuit patterns on the top surface and bottom surface of the singulated unit substrate are separated by a dielectric layer.

7-14. (canceled)

15. A semiconductor device comprising:
a singulated unit substrate comprising circuit patterns on a top surface and a bottom surface of the singulated unit substrate;
a semiconductor die bonded to the top surface of the singulated unit substrate;
an encapsulant film between the semiconductor die and the singulated unit substrate; and
a preimpregnated material (pre-preg) encapsulating the semiconductor die,
wherein side surfaces of the singulated unit substrate between the top surface and bottom surface of the singulated unit substrate are cut to be coplanar with side surfaces of the encapsulant film and the pre-preg.

16. The semiconductor device according to claim 15, wherein the semiconductor die is electrically coupled to the singulated unit substrate utilizing solder bumps.

17. The semiconductor device according to claim 15, wherein solder balls are formed on the circuit patterns on the bottom surface of the singulated unit substrate.

18. The semiconductor device according to claim 15, wherein an underfill material is formed between the semiconductor die and the top surface of the singulated unit substrate.

19. The semiconductor device according to claim 15, wherein the singulated unit substrate comprises conductive vias that electrically couple the circuit patterns on the top surface and bottom surface of the singulated unit substrate.

20. The semiconductor device according to claim 15, wherein the circuit patterns on the top surface and bottom surface of the singulated unit substrate are separated by a dielectric layer.

21. A semiconductor device comprising:
a singulated unit substrate comprising circuit patterns on a top surface and a bottom surface of the singulated unit substrate;
a semiconductor die bonded to the top surface of the singulated unit substrate;
an underfill between the semiconductor die and the singulated unit substrate; and
an encapsulating material encapsulating the underfill and the top surface of the singulated unit substrate,
wherein side surfaces of the singulated unit substrate between the top surface and bottom surface of the singulated unit substrate are coplanar with side surfaces of the encapsulating material.

22. The semiconductor device of claim 21, comprising interconnection structures that electrically connect the semiconductor die to the singulated unit substrate, and wherein the interconnection structures are encapsulated by the underfill.

23. The semiconductor device of claim 21, wherein the underfill and the encapsulating material are the same material.

24. The semiconductor device of claim 21, wherein the side surfaces of the singulated unit substrate are water-cut to be coplanar with the side surfaces of the encapsulating material.

25. The semiconductor device of claim 21, wherein the circuit patterns on the top and bottom surfaces of the singulated unit substrate are separated by at least a dielectric layer, and the singulated unit substrate comprises conductive vias that electrically couple the circuit patterns on the top and bottom surfaces of the singulated unit substrate.

26. The semiconductor device of claim 21, comprising a second encapsulating material that encapsulates the semiconductor die and the encapsulating material.

27. The semiconductor device of claim 26, wherein the encapsulating material comprises an encapsulant film, and the second encapsulating material comprises a preimpregnated material (pre-preg).

28. The semiconductor device of claim 26, wherein the second encapsulating material completely surrounds side and top surfaces of the semiconductor die.
